(19) United States
(12) Patent Application Publication
(10) Pub. No.: US 2016/0079558 A1
(43) Pub. Date: Mar. 17, 2016

(54) ORGANIC LIGHT EMITTING DEVICE AND ORGANIC LIGHT EMITTING DISPLAY INCLUDING THE SAME

(71) Applicant: SAMSUNG DISPLAY CO., LTD., Yongin-City (KR)

(72) Inventors: Jungmin MOON, Busan (KR); Jihoon SEO, Suwon-si (KR); ByungHoon CHUN, Yongin-si (KR)

(21) Appl. No.: 14/791,727

(22) Filed: Jul. 6, 2015

(30) Foreign Application Priority Data
Sep. 11, 2014 (KR) 10-2014-0120374

(51) Int. Cl. H01L 51/50; H01L 27/32; H01L 51/52

(52) U.S. Cl. CPC H01L 51/5088; H01L 51/5056; H01L 51/5012; H01L 51/5206; H01L 51/5221; H01L 51/5004; H01L 27/3276; H01L 27/3248; H01L 2251/552; H01L 51/005

(57) ABSTRACT

An organic light emitting device includes an anode, a hole function layer disposed on the anode, a light emitting layer disposed on the anode, and a cathode disposed on the light emitting layer. The hole function layer includes a main layer that does not include an n-type dopant and a p-type dopant. The hole function layer also includes a n-doped layer disposed between the main layer and the light emitting layer, and the n-doped layer includes an n-type dopant.

### CROSS-REFERENCE TO RELATED APPLICATION

This application claims priority from and the benefit of Korean Patent Application No. 10-2014-0120374, filed on Sep. 11, 2014, which is hereby incorporated by reference for all purposes as if fully set forth herein.

### BACKGROUND

1. Field

Exemplary embodiments relate to an organic light emitting device and an organic light emitting display including the same.

2. Discussion of the Background

Flat display devices are largely classified into a light emitting type and a light receiving type. The light emitting type flat panel displays include a flat cathode ray tube, a plasma display panel, and an organic light emitting display (OLED), etc. The OLED, as a self light emitting type display device, has a wide viewing angle, good contrast, and fast response speed.

Accordingly, the OLED gets attention since it may be applied to a display device for a mobile device such as a digital camera, a video camera, a camcorder, a personal digital assistant, a smart phone, an ultra-slim notebook, a tablet, or a personal computer, or a large electronic/electrical product such as an ultra-thin TV.

The OLED may realize colors using a principle in which holes and electrons injected to an anode and a cathode are recombined and emit a light in an organic light emitting layer when excitons generated from combinations of the injected holes and electrons decay from the excited state to the ground state.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a high quality organic light emitting device having improved light efficiency and life and a display device employing the same.

Additional aspects will be set forth in the detailed description which follows, and, in part, will be apparent from the disclosure, or may be learned by practice of the inventive concept.

An exemplary embodiment discloses organic light emitting devices including an anode, a hole function layer disposed on the anode, a light emitting layer disposed on the anode, and a cathode disposed on the light emitting layer. The hole function layer includes a main layer that does not include an n-type dopant and a p-type dopant. The hole function layer also includes a n-doped layer disposed between the main layer and the light emitting layer, and the n-doped layer includes an n-type dopant.

An exemplary embodiment also discloses an organic light emitting display device including an interconnection unit, a thin film transistor connected to the interconnection unit, and an organic light emitting device connected to the thin film transistor. The organic light emitting device includes an anode, a hole function layer disposed on the anode, a light emitting layer disposed on the anode, and a cathode disposed on the light emitting layer. The hole function layer includes a main layer that does not include an n-type dopant and a p-type dopant. The hole function layer also includes an n-doped layer disposed between the main layer and the light emitting layer, and the n-doped layer includes an n-type dopant.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a schematic cross-sectional view of an organic light emitting device according to an exemplary embodiment.

FIG. 2 is a schematic diagram illustrating an energy level of an organic light emitting device according to an exemplary embodiment.

FIG. 3 is a cross-sectional view of an organic light emitting device according to another exemplary embodiment.

FIG. 4 is a circuit diagram of one pixel when an organic light emitting device according to an exemplary embodiment is employed to a display device.

FIG. 5 is a plan view of the pixel illustrated in FIG. 4.

FIG. 6 is a cross-sectional view taken along line I-I′ of FIG. 5.

FIGS. 7 and 8 are graphs representing the luminance of existing comparative organic light emitting devices and organic light emitting devices according to exemplary embodiments.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result of manufacturing techniques and/or tolerances are to be expected. Thus, exemplary embodiments disclosed herein should not be construed as limited to the particular illustrated shapes of regions, but are to include deviations in shapes that result from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

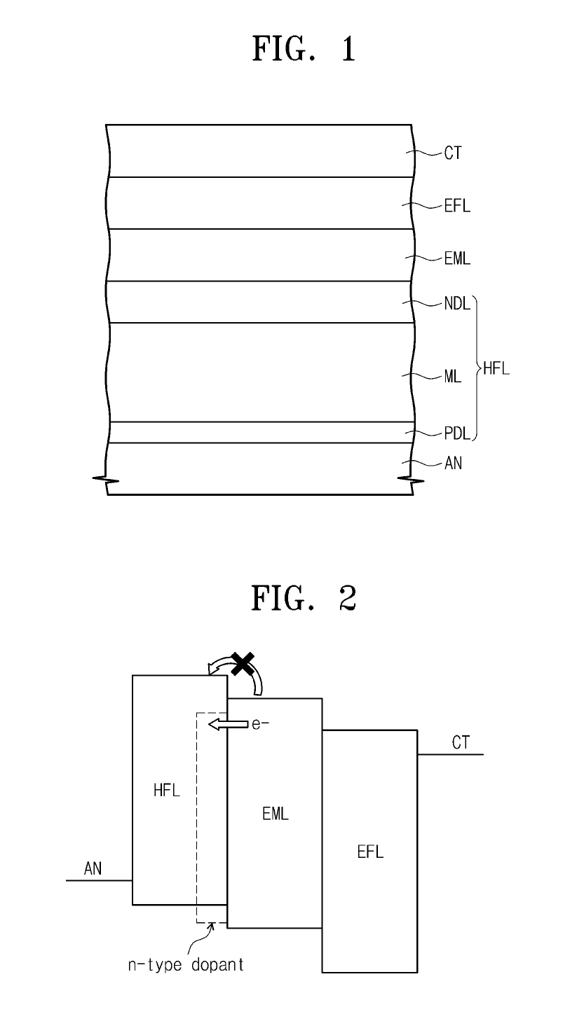

FIG. 1 is a schematic cross-sectional view of an organic light emitting device according to an exemplary embodiment.

Referring to FIG. 1, an organic light emitting device according to an exemplary embodiment includes an anode AN, a hole function layer HFL disposed on the anode AN, a light emitting layer EML disposed on the hole function layer HFL, and a cathode CT disposed on the light emitting layer EML. An electronic function layer EFL may be disposed between the light emitting layer EML and the cathode CT. In an exemplary embodiment, the electron function layer EFL may be omitted.

The anode AN is disposed on a substrate and has conductivity.

The substrate may be an insulating substrate formed from glass, quartz, an organic polymer, or the like. The organic polymer forming the substrate may include polyethylene terephthalate (PET), polyethylene naphthalate (PEN), polyimide, and polyether sulfone, and the like. The substrate may be selected in consideration of mechanical strength, thermal stability, transparency, surface smoothness, tractability, and water resistance, and the like.

The anode AN may be formed of a transparent metal oxide such as indium tin oxide (ITO), indium zinc oxide (IZO), zinc oxide (ZnO), and indium tin zinc oxide (ITZO), or the like, and may be formed by a method such as deposition or the like, before forming the hole function layer HTL.

The hole function layer HFL may be disposed on the anode AN. The hole function layer HFL facilitates injection and transport of holes to the light emitting layer EML.

In an exemplary embodiment, one or more kinds of hole injection materials and hole transport materials may be selected as a material for the hole function layer HFL.

The hole injection material may be, for example, but is not limited to, phthalocyanine compounds such as copper phthalocyanine, N,N′-diphenyl-N,N′-bis-[4-(phenyl-m-tolyl-amino)-phenyl]-biphenyl-4,4′-diamine (DNTPD), 4,4′,4″-tris(3-methylphenylphenylamino)triphenylamine (m-MTDATA), 4,4′4″-tris(N,N-diphenylamino)triphenylamine (TDATA), 4,4′,4″-tris{N,-(2-naphthyl)-N-phenylamino}-triphenylamine (2TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), or the like.

The hole transport material may be, for example, but is not limited to, carbazole derivatives such as N-phenylcarbazole, and polyvinylcarbazole, etc., triphenylamine-based derivatives such as N,N′-bis(3-methylphenyl)-N,N′-diphenyl-[1,1-biphenyl]-4,4′-diamine (TPD) etc., N,N′-di(1-naphthyl)-N,N′-diphenylbenzidine (NPB), 4,4′,4″-tris(N-carbazolyl)triphenylamine (TCTA), 4,4′-Cyclohexylidene bis[N,N-bis(4-methylphenyl)benzenamine] (TAPC), or the like.

The hole function layers HFL are classified into different layers according to whether a dopant is added to the hole function layer material and a kind of the dopant. In an exemplary embodiment, the hole function layer HFL may include an n-doped layer NDL into which an n-type dopant is doped and a main layer ML into which a dopant (an n-type or p-type dopant) is not doped. In an exemplary embodiment, the hole function layer (HFL) may further include a p-type doped layer PDL in which a p-type dopant is doped into the hole function layer material.

The p-doped layer PDL may be disposed between the anode AN and the light emitting layer EML. In an exemplary embodiment, the p-type doped layer PDL is disposed on the anode AN and directly contacts the anode AN. The p-type dopant doped into the hole function layer HFL may fill pores of the hole function layer material (host) to intensify interfacial stability between the anode AN and the hole function layer HFL, and lower a hole injection barrier. Accordingly, Joule heat at an interface between the anode AN and the hole function layer HFL may be reduced to stably provide holes to the light emitting layer EML, which improves efficiency and extends the luminance of the device.

The p-type dopant used in the p-doped layer PDL may be at least one selected from tetrafluoro-tetracyanoquinodimethane (F4-TCNQ), 1,4-anthraquinodirnethane (1,4-TCAQ), 15,15,16,16-tetracyano-6,13-pentacene-p-quinodimethane (6,3-TCPQ), tetracyanoanthraquinodimethane (TCAQ), 13,13,14,14-tetracyano-4,5,9,10-tetrahydropyrenoquinodimethane (TCNTHPQ), 13,13,14,14-tetracyanopyreno-2,7-quinodimethane (TCNPQ), phthalocyanine, FeCl₃, V₂O₅, WO₃, MoO₃, ReO₃, Fe₃O₄, MnO₂, SnO₂, CoO₂, and TiO₂.

Formula of each of F4-TCNQ, 1,4-TCAQ, 6,3-TCPQ, TCAQ, TCNTHPQ, and TCNPQ among the above-described compounds is expressed by the following Formula 1.

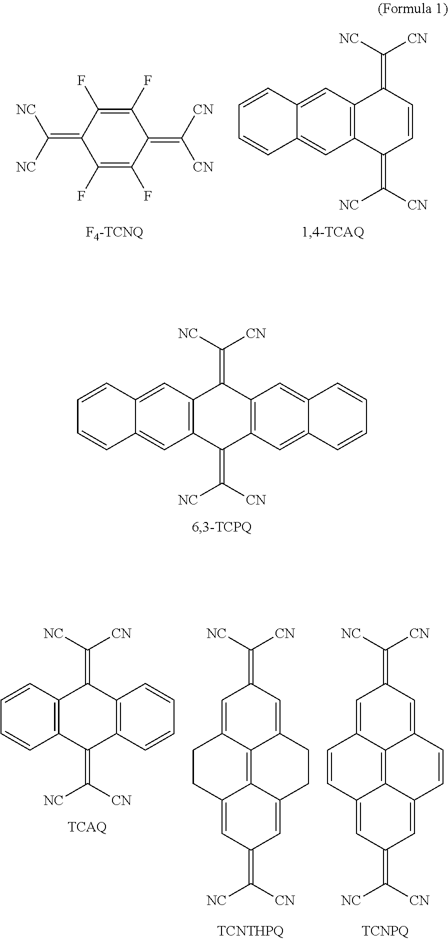

The p-doped layer PDL may be provided at a thickness ranging from about 50 Å to about 200 Å. The p-type dopant may be contained in the p-doped layer PDL at about 0.5 wt % to about 5 wt %. When the p-doped layer PDL is formed to have a thickness smaller than about 50 Å and/or the p-type dopant is contained at an amount of less than about 0.5 wt %, it is difficult to obtain intensified interfacial stability between the anode AN and the hole function layer HFL as well as a lowered hole injection barrier. When the p-doped layer PDL is formed to have a thickness greater than about 200 Å and/or the p-type dopant is contained at an amount of more than about 5 wt %, the hole injection barrier may be excessively lowered.

The main layer ML is disposed on the p-doped layer PDL. The main layer ML includes only the hole injection material and hole transport material. The main layer ML does not include an n-type dopant nor a p-type dopant.

The n-type doped layer NDL may be disposed between the p-doped layer PDL and the light emitting layer EML. The n-doped layer NDL directly contacts the light emitting layer EML. The n-type dopant doped into the hole function layer HFL prevents electrons from being leaked to the hole function layer HFL from the light emitting layer EML by lowering a lowest unoccupied molecular orbital (LUMO) level of the hole function layer HFL. For example, when the LUMO level of a host material (a hole injection material and/or a hole transport material) of the hole function layer HFL is referred to as a first LUMO level, the n-dopant has a second LUMO level lower than the first LUMO level. In an exemplary embodiment, a difference between the first and second LUMO levels may be greater than or equal to about 0.1 eV. In an exemplary embodiment, an electron mobility for the n-dopant may be greater than or equal to about 10⁻⁵cm²/Vs. In this case, the electrons easily move to the n-type dopant but not to the hole function layer material HFL.

The n-type dopant used for the n-doped layer NDL may be an organic or inorganic material. When the n-type dopant is an inorganic material, the n-type dopant may be an alkali metal such as Li, Na, K, Rb, Cs or Fr, an alkaline-earth metal such as Be, Mg, Ca, Sr, Ba or Ra, a rare-earth metal such as La, Ce, Pr, Nd, Sm, Eu, Tb, Th, Dy, Ho, Er, Em, Gd, Yb, Lu, Y or Mn, or a metal compound including one or more metals of the foregoing metals. When the n-type dopant is an organic material, the n-type dopant may be cyclopentadiene, cycloheptatriene, a 5-membered hetero ring or a material including an aromatic or aliphatic condensed ring containing the rings

The n-doped layer NDL may be provided at a thickness ranging from about 50 Å to about 500 Å. The n-type dopant may be contained in the n-doped layer NDL at about 0.5 wt % to about 10 wt %. When the n-doped layer NDL is formed to have a thickness smaller than about 50 Å and/or the n-type dopant is contained in an amount of less than about 0.5 wt %, it is difficult to obtain intensified interfacial stability between the anode AN and the hole function layer HFL as well as a lowered hole injection barrier. When the n-doped layer NDL is formed to have a thickness greater than about 500 Å or/and the n-type dopant is contained in an amount of more than about 10 wt %, the electron injection barrier may be excessively lowered and charges may be excessively accumulated in the n-type doped layer NDL.

In the p-doped layer PDL, the p-type dopant may be dispersed homogeneously or unhomogeneously, or distributed to have a concentration gradient. In addition, in the n-doped layer NDL, the n-type dopant may be dispersed homogeneously or unhomogeneously, or distributed to have a concentration gradient.

In an exemplary embodiment, the hole function layer HFL may be classified into a multilayer according to a host material (namely, a hole function layer material) included in the hole function layer HFL, independently from multilayer classification according to whether a dopant is doped. For example, the hole function layer HFL may have the hole injection layer and the hole transport layer sequentially stacked on the anode AN, and the hole injection layer and the hole transport layer may include one of the foregoing hole injection materials and one of the hole transport materials, respectively.

Furthermore, in an exemplary embodiment, each of the p-doped layer PDL, the main layer ML, and the n-doped layer NDL forming the hole function layer HFL may include the same or different hole transport materials and/or hole injection materials. In an exemplary embodiment, at least one of the hole transport material and the hole injection material may be triphenylamine.

The light emitting layer EML may include, as the host material, tris(8-quinolinolate)aluminum (Alq3), 4,4′-bis(N-carbazolyl)-1,1′-biphenyl (CBP), poly(n-vinylcabazole) (PVK), 9,10-di(naphthalene-2-yl)anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), etc. The light emitting layer EML may include, as a dopant, various dopants such as a fluorescence dopant or a phosphorescent dopant. The phosphorescent dopant may be Ir, Pt, Os, Re, Ti, Zr, Hf or an organometallic complex including a combination of two or more thereof.

In an exemplary embodiment, a red dopant may include Pt(II) octaethylporphine (PtOEP), tris(2-phenylisoquinoline)iridium (Ir(piq)3), bis(2-(2′-benzothienyl)-pyridinato-N,C3′)iridium(acetylacetonate) (Btp2Ir(acac)), etc.

In an exemplary embodiment, a green dopant may include tris(2-phenylpyridine)iridium (Ir(ppy)3), Bis(2-phenylpyridine)(Acetylacetonato)iridium(III) (Ir(ppy)2(acac)), tris(2-(4-tolyl)phenylpiridine)iridium (Ir(mppy)3), 10-(2-benzothiazolyl)-1,1,7,7-tetramethyl-2,3,6,7-tetrahydro-1H,5H,11H-[1]benzopyrano[6,7,8-ij]-quinolizin-11-one) (C545T), etc.

In an exemplary embodiment, a blue dopant may include bis[3,5-difluoro-2-(2-pyridyl)phenyl](picolinato)iridium(III) (F2lrpic), (F2ppy)2Ir(tmd), Ir(dfppz)3,4,4′-bis(2,2′-diphenylethen-1-yl)biphenyl (DPVBi), 4,4′-Bis[4-(diphenylamino)styryl]biphenyl (DPAVBi), 2,5,8,11-tetra-tert-butylperylene (TBPe), etc.

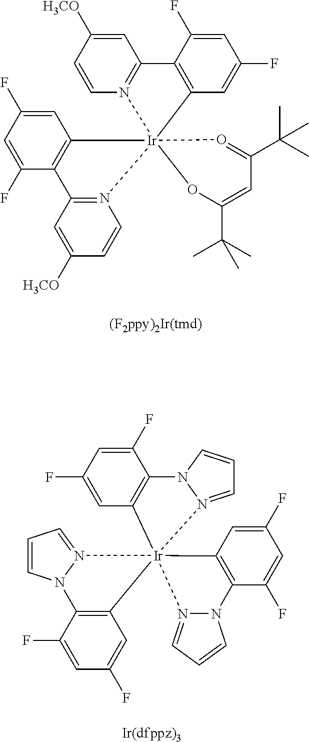

An electron function layer EFL may be disposed on the light emitting layer EML. The electron function layer EFL may facilitate injection and transport of electrons to the light emitting layer EML and be formed in a single layer or a multi-layer. When the electron function layer EFL is provided in a multi-layer, the electron function layer EFL may include an electron transport layer and an electron injection layer sequentially stacked on the light emitting layer EML.

The electron function layer EFL may include one or more of an electron injection layer material and an electron transport layer material to be described later.

The electron transport layer material may include, for example, tris(8-hydroxyquinolinato)aluminum (Alq3), 1,3,5-Tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), Bis(2-methyl-8-quinolinolato-N1,O8)-(1,1′-Biphenyl-4-olato)aluminum (BAlq), berylliumbis(benzoquinolin-10-olate) (Bebq2), 9,10-di(naphthalene-2-yl)anthracene (ADN), etc.

The electron injection layer material may include a metal containing material. The metal containing material includes LiF, Lithium quinolate (LiQ), Li₂O, BaO, NaCl, CsF, or the like. In addition, the electron injection layer material may include a material in which the electron transport material and an organo metal salt having insulation property are mixed. The organo metal salt may be a material having an energy bad gap of approximately 4 eV or greater. In detail, for example, the organo metal salt may include metal acetate, metal benzoate, metal acetoacetate, metal acetylacetonate, or metal stearate.

The cathode CT may be formed from a metal or an alloy having a low work function, or an electrically conductive compound, or a mixture thereof. For example, the cathode CT may be formed from lithium (Li), magnesium (Mg), Al, aluminum-lithium (Al—Li), calcium (Ca), magnesium-indium (Mg—In), or magnesium-silver (Mg—Ag).

In an organic light emitting device having the foregoing structure, as voltages are applied to the anode AN and the cathode CT respectively, holes injected from an electrode of the anode AN move to the light emitting layer EML, and electrons injected from an electrode of the cathode CT move to the light emitting layer EML through the electron transport layer ETL. The electrons and the holes are recombined in the light emitting layer EML to create excitons and the excitons decay from an excited state to the ground state to emit a light.

The light emitting device having the foregoing structure allows the electrons and holes to be stably injected and transported to the light emitting layer EML, and accordingly, has improved light emitting efficiency. Accordingly, the organic light emitting device having the foregoing structure has improved optical and electrical performance.

FIG. 2 is a schematic diagram illustrating an energy level of an organic light emitting device according to an exemplary embodiment.

Referring to FIG. 2, the hole function layer HFL material has higher LUMO level than the light emitting layer EML material. In contrast, the n-type dopant has a lower LUMO level than the light emitting layer EML material. In other words, when the LUMO level of the hole function layer HFL material is referred to as a first LUMO level and the LUMO level of the n-type dopant is referred to as a second LUMO level, the first LUMO level is higher than the second LUMO level.

Accordingly, the electrons in the light emitting layer EML move to the n-type dopant having the lower LUMO level, rather than the hole function layer HFL material. In other words, when n-type dopants are doped into a part area of the hole function layer (HFL) from an interface between the hole function layer HFL and the light emitting layer EML, the n-type dopants act as an electron leakage path. Accordingly, the electrons are prevented from moving to an important part of the hole function layer HFL, in particular, to the main layer ML from the light emitting layer EML, while a phenomenon in which the electrons are excessively accumulated on the interface between the light emitting layer EML and the hole function layer HFL is reduced.

Generally, reduction of life of the organic light emitting device (e.g., the reduction of luminance of the organic light emitting device) is caused by electron accumulation in the hole function layer HFL. In particular, the leaked electrons from the light emitting layer EML are combined with the holes to form excitons in the hole function layer HFL. The excitons decay to the ground state without light emission inside the hole function layer HFL and cause degradations of the hole function layer HFL and the light emitting layer EML at the interface between the hole function layer HFL and the light emitting layer EML, and, at the same time, reduces the light emission efficiency of the organic light emitting device. Accordingly, in order to obtain high light emitting efficiency and prevent degradations of the hole function layer HFL and the light emitting layer EML, a high hole concentration is required to be maintained in proper balance in the hole function layer HFL and, at the same time, to prevent inflow of the electrons from the light emitting layer EML. To this end, in the existing invention, a separate buffer layer is formed of a material having a very high LUMO level (i.e., an LUMO level higher than the light emitting layer EML).

However, in order to address the foregoing issue, an electron leakage path is formed from a material having a lower LUMO level than the light emitting layer EML on a top portion of the hole function layer HFL to prevent inflow of the electrons from the light emitting layer EML. Accordingly, exciton formation is prevented in the hole function layer HFL by the n-type dopants and life of the device improves. Even though the excitons are formed by the n-type dopants, since light emitting energy thereof is lower than that of the hole function layer HFL material, the life of the light emitting device is not largely affected.

On the other hand, according to an exemplary embodiment, a highest occupied molecular orbital (HOMO) level of the n-type dopant may be positioned between a HOMO level of the hole function layer HFL material and a HOMO level of the light emitting layer EML material, but the inventive concept is not limited hereto. For example, the n-type dopant may have lower HOMO level than the light emitting layer EML material. However, even in this case, the HOMO level of the n-type dopant may be maintained to be substantially the same (e.g., a difference between the two HOMO levels is not greater than 0.1 eV) as that of the light emitting layer EML material. When the n-type dopant has a HOMO level too low when compared to the light emitting layer EML material, the holes are difficult to inject to the light emitting layer EML and holes are accumulated on an interface between the hole function layer HFL and the light emitting layer (EML), which becomes another cause of the life reduction.

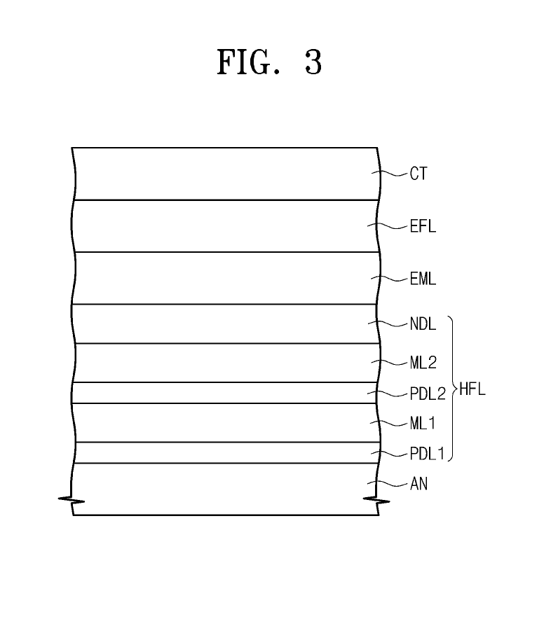

FIG. 3 is a cross-sectional view of an organic light emitting device according to another exemplary embodiment.

In another exemplary embodiment and in order to avoid redundancy of explanation, points different from the organic light emitting device according to the embodiment illustrated in FIG. 1 will be mainly explained, while parts that are described with reference to FIG. 1 will not be explained.

Referring to FIG. 3, according to the other exemplary embodiment, a structure of the hole function layer HFL may be different than the one illustrated in FIG. 1. In particular, the p-doped layer into which the p-type dopant is doped may be provided in a plurality of layers. The p-doped layers are disposed between the anode AN and the n-doped layer NDL and the adjacent p-doped layers are separated from each other with the main layer in-between.

For example, the p-doped layer may be provided in two layers and the two layers may be referred to as a first p-doped layer PDL1 and a second p-doped layer PDL2. The main layer may also be provided in a plurality of layers according to the number of the p-doped layers and the two layers may be referred to as a first main layer ML1 and a second main layer ML2. In this case, the first p-doped layer PDL 1, the first main layer ML1, the second p-doped layer PDL2, and the second main layer ML2 are sequentially stacked on the anode AN.

While the exemplary embodiment of FIG. 3 describes that the p-doped layers are formed in two layers, the inventive concept is not indented to be limited to such an embodiment. In another exemplary embodiment, the p-doped layers may have three or more layers.

In an exemplary embodiment, the first p-dope layer PDL1 closer to the anode AN and between the anode AN and second p-type doped layer PDL2 directly contacts the anode AN. The first p-doped layer PDL1 directly contacting the anode AN between the anode AN and the second p-doped layer PDL2 may improve interfacial stability between the anode AN and the hole function layer HFL and lower the hole injection barrier. The second p-doped layer PDL2 between the main layers ML1 and ML2 may improve the hole mobility to allow the holes to be stably provided to the light emitting layer EML.

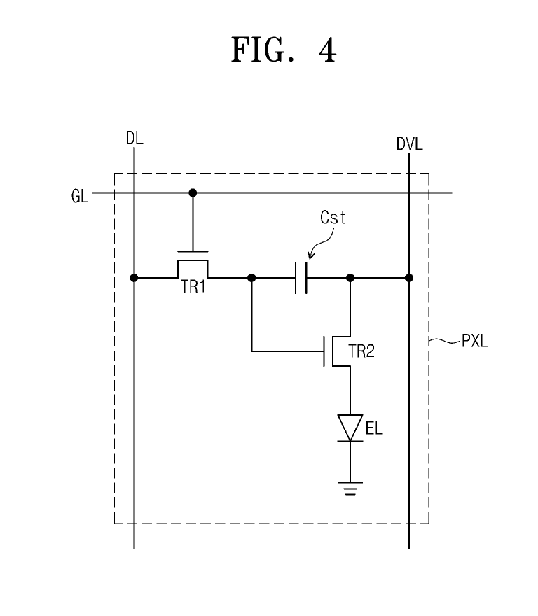

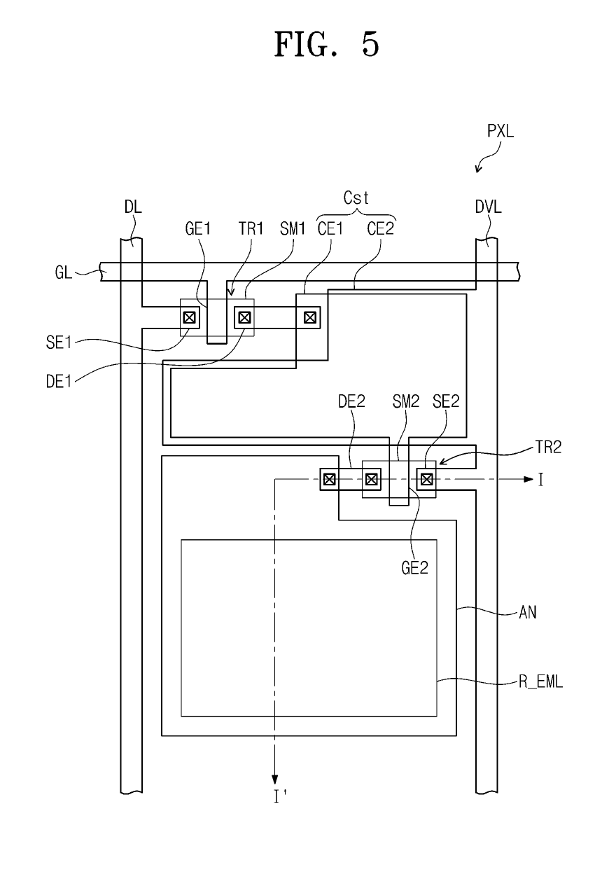

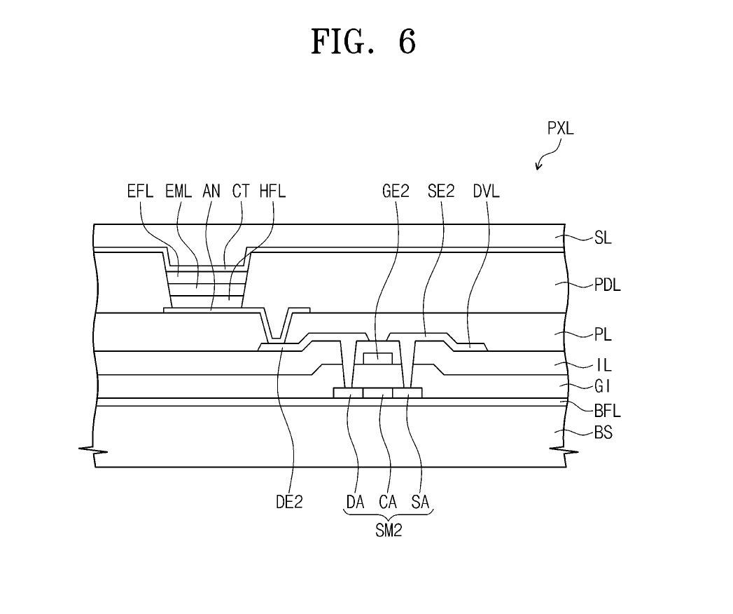

FIG. 4 is a circuit diagram of one pixel when an organic light emitting device according to an exemplary embodiment is employed in a display device. FIG. 5 is a plan view of the pixel illustrated in FIG. 4. FIG. 6 is a cross-sectional view taken along line I-I′ of FIG. 5.

Hereinafter, description is provided about a display device employing an organic light emitting device according to an exemplary embodiment with reference to FIGS. 4 to 6.

A display device according to an exemplary embodiment includes at least one pixel PXL displaying an image. A plurality of pixels PXL may be arrayed in a matrix and each pixel may emit a specific color light. For example, one pixel may emit a red light, a green light, or a blue light. The color emitted by the pixels is not limited to red, green, and blue. The color may be any other color such as cyan, magenta, or yellow.

In the display device according to an exemplary embodiment, at least one pixel PXL emits a blue light, and the pixel PXL emitting the blue light is described below.

The pixel PXL includes an interconnection unit including a gate line GL, a data line DL, and a driving voltage line DVL, a thin film transistor connected to the interconnection unit, an organic light emitting device connected to the thin film transistor, and a capacitor Cst.

The gate line GL extends in one direction. The data line DL extends in another direction (i.e., substantially perpendicular direction) and intersects with the gate line GL. The driving voltage line DVL extends in substantially the same direction as the data line DL. The gate line GL delivers a scan signal to the thin film transistor, the data line DL delivers a data signal to the thin film transistor, and the driving voltage line DVL provides a driving voltage to the thin film transistor.

The thin film transistor may include a driving thin film transistor TR2 for controlling the organic light emitting device and a switching thin film transistor TR1 for switching the driving thin film transistor TR2. While an exemplary embodiment describes that one pixel PXL includes two thin film transistors TR1 and TR2, the inventive concept is not limited to such an embodiment. For example, one pixel PXL may include one thin film transistor and capacitor Cst, or one pixel PXL may include three or more thin film transistors and two or more capacitors Csts.

The switching thin film transistor TR1 may include a first gate electrode GE1, a first source electrode SE1, and a first drain electrode DE1. The first gate electrode GE1 is connected to the gate line GL, and the first source electrode SE1 is connected to the data line DL. The first drain electrode DE1 is connected to a gate electrode (namely, the second gate electrode GE2) of the driving thin film transistor TR2. The switching thin film transistor TR1 delivers a data signal applied to the data line DL to the driving thin film transistor TR2 according to a scan signal applied to the gate line GL.

The driving thin film transistor TR2 includes the second gate electrode GE2, a second source electrode SE2, and a second drain electrode DE2. The second gate electrode GE2 is connected to the switching thin film transistor TR1. The second source electrode SE2 is connected to the driving voltage line DVL. Additionally, the second drain electrode DE2 is connected to the organic light emitting device.

The organic light emitting device is substantially the same as the organic light emitting device according to the above-described embodiments.

The capacitor Cst is connected between the second gate electrode GE2 and the second source electrode SE2 of the driving thin film capacitor TR2. The capacitor Cst charges and maintains the data signal input to the second gate electrode GE2 of the driving thin film transistor TR2.

A common voltage is applied to the cathode CT. The light emitting layer EML displays an image by emitting a blue light according to an output signal of the driving thin film transistor TR2.

Hereinafter, a display device having a stack sequence is described according to an exemplary embodiment.

A display device according to an exemplary embodiment includes a base substrate BS formed from glass, plastic, or a crystal. The base substrate BS may act as an insulator for the thin film transistor and the organic light emitting device stacked on the base substrate BS.

A buffer layer BFL is formed on the base substrate BS. The buffer layer BFL prevents dopants from being spread to the switching and driving thin film transistors TR1 and TR2. The buffer layer BFL may be formed from silicon nitride (SiNₓ), silicon oxide (SiOₓ), or silicon oxynitride (SiOₓN_{y}), etc., or may be omitted according to a material of the base substrate BS and certain processing.

A first semiconductor layer SM1 and a second semiconductor layer SM2 are disposed on the buffer layer BFL. The first and second semiconductor layers SM1 and SM2 are formed from semiconductor materials and respectively operate as activation layers of the switching thin film transistor TR1 and the driving thin film transistor TR2. The first and second semiconductor layers SM1 and SM2 include source areas SA, drain areas DA, and channel areas CA disposed between the source areas SA and the drain areas DA. The first and second semiconductor layers SM1 and SM2 may be respectively formed from a selected inorganic semiconductor and an organic semiconductor. The source area SA and the drain area DA may be doped with a n-type dopant or a p-type dopant.

A gate insulating film GI is disposed on the first and second semiconductor layers SM1 and SM2.

The first gate electrode GE1 and the second gate electrode GE2 connected to the gate line GL are disposed on the gate insulating film GI. The first and second gate electrodes GE1 and GE2 are formed to cover areas corresponding to the channel areas CA of the first and second semiconductor layers SM1 and SM2, respectively.

An interlayer insulating film IL is disposed to cover the first and second gate electrodes GE1 and GE2.

The first source electrode SE1 and the first drain electrode DE1, the second source electrode SE2 and the second drain electrode DE2 are disposed on the interlayer insulating film IL. The first source electrode SE1 and the first drain electrode DE1 respectively contact the source area SA and the drain area DA of the first semiconductor layer SM1 through contact holes formed in the gate insulating film GI and the interlayer insulating layer IL (not shown). The second source electrode SE2 and the second drain electrode DE2 respectively contact the source area SA and the drain area DA of the second semiconductor layer SM2 through contact holes formed in the gate insulating film GI and the interlayer insulating layer IL.

A passivation layer PL is disposed on the first source electrode SE1 and the first drain electrode DE1, and the second source electrode SE2 and the second drain electrode DE2. The passivation layer PL may protect the switching and driving thin film transistors TR1 and TR2 and/or may planarize a top surface of the passivation layer (PL).

The anode AN of the organic light emitting device is disposed on the passivation layer PL. The anode AN is connected to the second drain electrode DE2 of the driving thin film transistor TR2 through a contact hole formed through the passivation layer PL.

A pixel defining layer PDL dividing a pixel area PA is disposed to correspond to each pixel on the base substrate BS on which the anode AN etc., is formed. The pixel defining layer PDL exposes a top surface of the anode AN and protrudes from the base substrate BS along the perimeter of the pixel PXL.

The hole function layer HFL, the light emitting layer EML, the electron function layer EFL are sequentially disposed on the pixel area PA surrounded by the pixel defining layer PDL. The cathode CT is disposed on the electron function layer EFL.

A sealing layer SL covering the cathode CT is disposed on the cathode CT.

The organic light emitting diodes according to the above-described embodiments show higher luminance in contrast to an existing organic light emitting device.

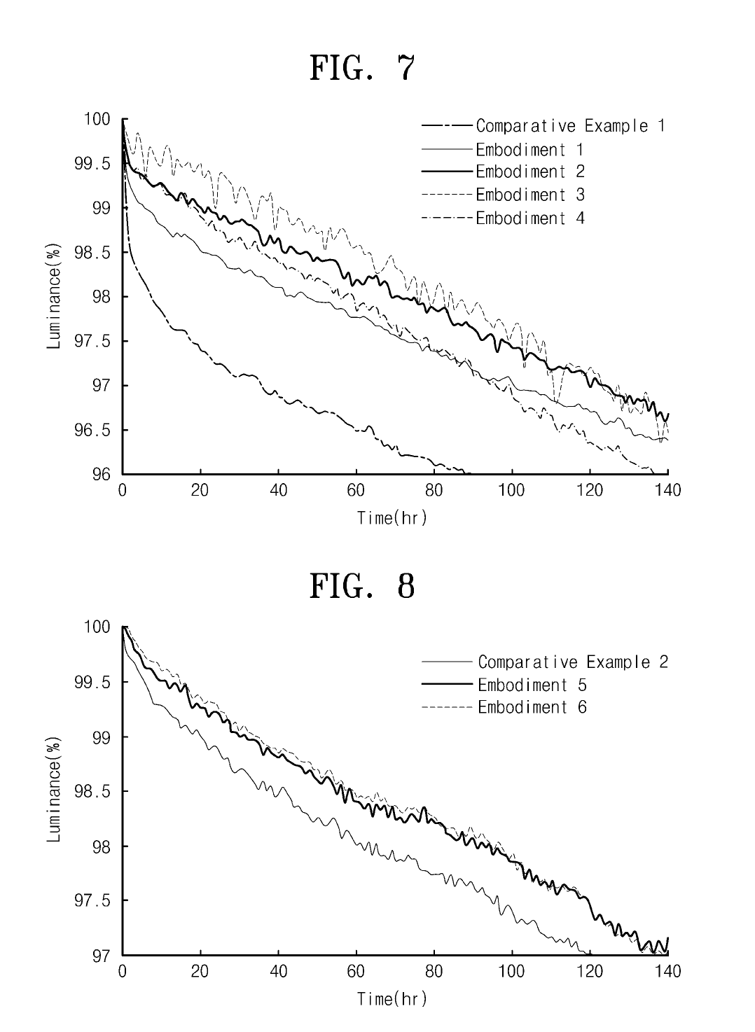

FIG. 7 is a graph representing luminance of an existing organic light emitting device and organic light emitting devices according to an exemplary embodiments. In FIG. 7, Comparative Example 1 is an organic light emitting device with layers stacked in the following order: an anode, a hole function layer, a light emitting layer, an electronic function layer, and a cathode. Embodiments 1, 2, 3, and 4 have the same structure as Comparative Example 1 except for the hole function layer. Embodiments 1, 2, 3,and 4 have the structure illustrated in FIG. 3. Embodiments 1, 2, 3, and 4 were manufactured with the same materials and under the same condition as Comparative Example 1 except with respect to the n-doped layer and p-doped layer. Additional differences between the Comparative Example 1, Embodiment 1, Embodiment 2, Embodiment 3, and Embodiment 4 lie in a thickness of the n-doped layer and the concentration of the n-type dopant. The thickness of the n-doped layer and concentration of the n-type dopant of the Comparative Example 1 and Embodiments 1, 2, 3, and 4 are represented in Table 1.

TABLE 1

| | Doping condition of n-type dopant (thickness, |
|---|---|
| Condition | concentration) |
| Comparative Example 1 | 450 Å, 0 wt % |
| Embodiment 1 | 450 Å, 1 wt % |
| Embodiment 2 | 450 Å, 3 wt % |
| Embodiment 3 | 450 Å, 5 wt % |
| Embodiment 4 | 50 Å, 5 wt % |

The hole function layer materials used in Comparative Example 1 and Embodiments 1, 2, 3, and 4 are expressed with the following formula.

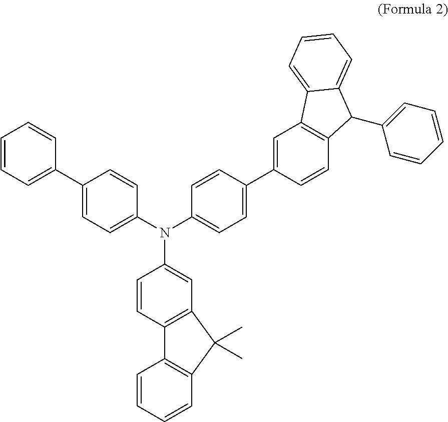 [SMILES: CC1(C)c2ccccc2-c2ccc(N(c3ccc(-c4ccccc4)cc3)c3ccc(-c4ccc5c(c4)-c4ccccc4C5c4ccccc4)cc3)cc21]

The HOMO levels and LUMO levels of the materials used in Comparative Example 1 and Embodiments 1, 2, 3, and 4 are expressed in Table 2.

TABLE 2

| | LUMO (eV) | HOMO (eV) |
|---|---|---|
| Hole function layer material | −2.39 | −5.34 |
| N-type dopant | −2.9 | −5.65 |
| Light emitting layer material | −2.7 | −5.6 |

Referring to FIG. 7, Comparative Example 1, which does not have an n-doped layer or a p-doped layer, may decrease luminance at an exponential rate while Embodiments 1, 2, 3, and 4 which have an n-type doped layer or p-type doped layer decrease luminance at a linear rate. In other words, Comparative Example 1 and Embodiments 1, 2, 3, and 4 all decrease luminance over time. However, Comparative Example 1 decreases in luminance faster (i.e., exponentially) than Embodiments 1, 2, 3, and 4. For example, Comparative Example 1 has a luminance of 96% at approximately 90 hours while Embodiments 1, 2, 3, and 4 all have a luminance greater than 97% at the same time. The luminance of Embodiments 1, 2, 3, and 4 does not depend greatly on a thickness or concentration of the n-type dopant. However, embodiments with thicker n-type doped layer have a higher luminance over time than embodiments with thinner n-type-doped layers.

FIG. 8 is a graph representing luminance of an existing organic light emitting device and organic light emitting devices according to an exemplary embodiments. In FIG. 8, Comparative Example 2 has a structure stacked in the following order: an anode, a hole function layer, a light emitting layer, an electronic function layer, and a cathode. Embodiments 5 and 6 is the same as Comparative Example 2 except for the hole function layer. Embodiments 5 and 6 have the structure illustrated in FIG. 3. More specifically, Embodiments 5 and 6 have a p-doped layer and a main layer comprising a compound represented by Formula 2. In addition, Embodiments 5 and 6 have a hole function layer material and an n-doped layer comprising a compound represented by Formula 3.

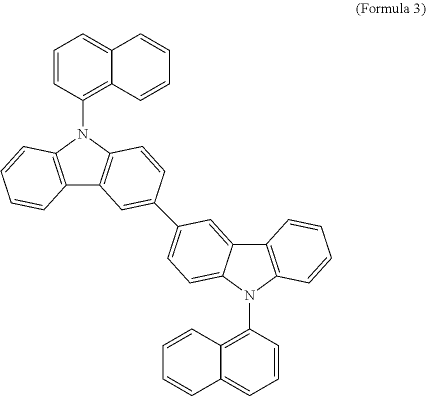 [SMILES: c1ccc2c(-n3c4ccccc4c4cc(-c5ccc6c(c5)c5ccccc5n6-c5cccc6ccccc56)ccc43)cccc2c1]

Thickness of the n-doped layer and concentration of the n-type dopant of Embodiments 5 and 6 are represented in Table 3.

TABLE 3

| | Doping condition of n-type dopant |
|---|---|
| Condition | (thickness, concentration) |
| Comparative Example 2 | 350 Å, 0 wt % |
| Embodiment 5 | 350 Å, 5 wt % |
| Embodiment 6 | 350 Å, 10 wt % |

The HOMO levels and LUMO levels of the materials used in the Comparative Example 2 and Embodiments 5 and 6 are expressed in Table 4.

TABLE 4

| | LUMO (eV) | HOMO (eV) |
|---|---|---|
| P-doped layer and main layer material | −2.39 | −5.34 |
| N-doped layer material | −2.28 | −5.57 |
| N-type dopant material | −2.9 | −5.65 |
| Light emitting layer material | −2.5 | −5.4 |

Referring to FIG. 8, Comparative Example 2, which does not have an n-doped layer or a p-doped layer, decrease in luminance faster than Embodiments 5 and 6, which have an n-doped layer or a p-doped layer is provided. In other words, Comparative Example 2 and Embodiments 5 and 6 all decrease in luminance over time, but Comparative Example 2 decreases at a faster rate. The luminaces of Embodiments 5 and 6 do not depend greatly on a thickness or concentration of the n-type dopant. However, embodiments with thicker n-type doped layer have a higher luminance over time than embodiments with thinner n-type-doped layers

While this invention has been described with reference to exemplary embodiments thereof, it will be clear to those of ordinary skill in the art to which the invention pertains that various changes and modifications may be made to the described embodiments without departing from the spirit and technical area of the invention as defined in the appended claims and their equivalents. For example, exemplary embodiments are presented to have different structures respectively, but it is of course that elements can be combined or replaced with each other unless the elements are incompatible.

Although this application discloses a structure that an anode is formed on a substrate first, the inventive concept is not limited to such an embodiment. Instead, the inventive concept is intended to include different disposed positions of the anode and the cathode and different disposed positions of the function layers disposed between the anode and the cathode.

According to exemplary embodiments, a high quality organic light emitting device and a display device employing the same can be provided.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. An organic light emitting device, comprising:
an anode;
a hole function layer disposed on the anode;
a light emitting layer disposed on the anode; and
a cathode disposed on the light emitting layer,
wherein the hole function layer comprises:
a main layer that does not comprise an n-type dopant and a p-type dopant; and
a n-doped layer disposed between the main layer and the light emitting layer and the n-doped layer comprising an n-type dopant.

2. The organic light emitting device of claim 1, wherein the n-doped layer contacts the light emitting layer.

3. The organic light emitting device of claim 2, wherein:
the hole function layer comprises at least one of a hole transport material and a hole injection material, and
the hole function layer comprises a first lowest unoccupied molecular orbital (LUMO) level and the n-type dopant comprises a second LUMO that is lower than the first LUMO level.

4. The organic light emitting device of claim 3, wherein a difference between the first and second LUMO levels is greater than or equal to 0.1 eV.

5. The organic light emitting device of claim 3, wherein the n-type dopant comprises at least one of an alkali metal, an alkaline-earth metal, a rare-earth metal, a metal compound comprising one or more metals, cyclopentadiene, cycloheptatriene, an aromatic or aliphatic 5-membered hetero-ring compound, and an aromatic or aliphatic compound comprising 5-membered hetero-ring.

6. The organic light emitting device of claim 5, wherein n-doped layer comprises about 0.5 wt % to about 10 wt % of n-type dopant.

7. The organic light emitting device of claim 1, wherein the hole function layer further comprises a p-doped layer disposed between the anode and the n-doped layer, and wherein the p-doped layer comprises the p-type dopant.

8. The organic light emitting device of claim 7, wherein the p-doped layer contacts the anode.

9. The organic light emitting device of claim 7, wherein the p-type dopant comprises at least one of tetrafluoro-tetracyanoquinodimethane (F4-TCNQ), 1,4-anthraquinodirnethane (1,4-TCAQ), 15,15,16,16-tetracyano-6,13-pentacene-p-quinodimethane (6,3-TCPQ), tetracyanoanthraquinodimethane (TCAQ), 13,13,14,14-tetracyano-4,5,9,10-tetrahydropyrenoquinodimethane (TCNTHPQ), 13,13,14,14-tetracyanopyreno-2,7-quinodimethane (TCNPQ), phthalocyanine, FeCl₃, V₂O₅, WO₃, MoO₃, ReO₃, Fe₃O₄, MnO₂, SnO₂, CoO₂, and TiO₂.

10. The organic light emitting device of claim 9, wherein the p-doped layer comprises about 0.5 wt % to about 5 wt % of the p-type dopant.

11. The organic light emitting device of claim 7, wherein the p-doped layer comprises a plurality of layers separated from each other, and the p-doped layer closest to the anode, among the plurality of p-doped layers, contacts the anode.

12. The organic light emitting device of claim 1, wherein:
the hole function layer comprises at least one of a hole transport material and a hole injection material, and the at least one of the hole transport material and the hole injection material comprising a p-doped layer, the main layer, and the n-dope layer of the hole function layer are different.

13. The organic light emitting device of claim 12, wherein the at least one of the hole transport material and the hole injection material is triphenylamine.

14. An organic light emitting display device, comprising:
an interconnection unit;
a thin film transistor connected to the interconnection unit; and
an organic light emitting device connected to the thin film transistor,
wherein the organic light emitting device comprises:
an anode;
a hole function layer disposed on the anode;
a light emitting layer disposed on the anode; and
a cathode disposed on the light emitting layer,
wherein the hole function layer comprises:
a main layer that does not comprise an n-type dopant and a p-type dopant; and
a n-doped layer disposed between the main layer and the light emitting layer and the n-doped layer comprising an n-type dopant.

15. The organic light emitting display device of claim 14, wherein the n-doped layer contacts the light emitting layer.

16. The organic light emitting display device of claim 15, wherein:
the hole function layer comprises at least one of a hole transport material and a hole injection material, and
the hole function layer comprises a first lowest unoccupied molecular orbital (LUMO) level and the n-type dopant comprises a second LUMO level lower than the first LUMO level.

17. The organic light emitting display device of claim 16, wherein a difference between the first and second LUMO levels is greater than or equal to about 0.1 eV.

18. The organic light emitting display device of claim 14, wherein the hole function layer further comprises a p-doped layer disposed between the anode and the n-doped layer and wherein the p-doped layer comprises a p-type dopant.

19. The organic light emitting display device of claim 18, wherein the p-doped layer contacts the anode.

20. The organic light emitting display device of claim 18, wherein the p-doped layer comprises a plurality of layers separated from each other and the p-doped layer closest to the anode, among the plurality of p-doped layers, contacts the anode.
